(19) United States
(12) Patent Application Publication
(10) Pub. No.: US 2004/0031565 A1
(43) Pub. Date: Feb. 19, 2004

(54) Gas distribution plate for processing chamber

(75) Inventors: Ying-Zhong Su, Hsin-Chu (TW); Wen-Chi Wang, Hsin-Chu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/217,370

(22) Filed: Aug. 13, 2002

(51) Int. Cl. C23F 1/00; C23C 16/00

(52) U.S. Cl. 156/345.33; 156/345.34; 118/715

(57) ABSTRACT

A new and improved gas distribution plate for a processing chamber for substrates. The gas distribution plate is provided with multiple gas distribution openings which are larger in size in the peripheral or edge regions of the plate than are the openings in the central region of the plate. The larger openings in the peripheral or edge regions of the plate provide a greater area for gas distribution through the plate than the smaller openings in the central region of the plate in order to compensate for the normally higher rate of plasma flow through the center region of the plate.

### FIELD OF THE INVENTION

The present invention relates to gas distribution plates for distributing process gases into a process chamber for semiconductors. More particularly, the present invention relates to a gas distribution plate which facilitates improved flow uniformity of gas flowing into a process chamber for semiconductors.

### BACKGROUND OF THE INVENTION

The fabrication of various solid state devices requires the use of planar substrates, or semiconductor wafers, on which integrated circuits are fabricated. The final number, or yield, of functional integrated circuits on a wafer at the end of the IC fabrication process is of utmost importance to semiconductor manufacturers, and increasing the yield of circuits on the wafer is the main goal of semiconductor fabrication. After packaging, the circuits on the wafers are tested, wherein non-functional dies are marked using an inking process and the functional dies on the wafer are separated and sold. IC fabricators increase the yield of dies on a wafer by exploiting economies of scale. Over 1000 dies may be formed on a single wafer which measures from six to twelve inches in diameter.

Various processing steps are used to fabricate integrated circuits on a semiconductor wafer. These steps include deposition of a conducting layer on the silicon wafer substrate; formation of a photoresist or other mask such as titanium oxide or silicon oxide, in the form of the desired metal interconnection pattern, using standard lithographic or photolithographic techniques; subjecting the wafer substrate to a dry etching process to remove the conducting layer from the areas not covered by the mask, thereby etching the conducting layer in the form of the masked pattern on the substrate; removing or stripping the mask layer from the substrate typically using reactive plasma and chlorine gas, thereby exposing the top surface of the conductive interconnect layer; and cooling and drying the wafer substrate by applying water and nitrogen gas to the wafer substrate.

The numerous processing steps outlined above are used to cumulatively apply multiple electrically conductive and insulative layers on the wafer and pattern the layers to form the circuits. The final yield of functional circuits on the wafer depends on proper application of each layer during the process steps. Proper application of those layers depends, in turn, on coating the material in a uniform spread over the surface of the wafer in an economical and efficient manner.

During the photolithography step of semiconductor production, light energy is applied through a reticle mask onto a photoresist material previously deposited on the wafer to define circuit patterns which will be etched in a subsequent processing step to define the circuits on the wafer. In the case of positive photoresist, the photoresist is evenly and completely removed from all areas unexposed to the light. The remaining exposed patterns define various active regions of integrated circuits on the wafer, such as, for example, diffusion regions, gate regions, contact regions, or interconnection regions. The patterned photoresist is used as a masking material to form the circuit patterns on the substrate during etching to protect selected areas on the surface of the substrate from etchant which selectively etches the unprotected areas on the surface of the substrate.

Photoresist materials are coated onto the surface of a wafer by dispensing a photoresist fluid typically on the center of the wafer as the wafer rotates at high speeds within a stationary bowl or coater cup. After deposition of the photoresist, it is desired to measure the critical dimensions of the pattern as well as to verify the integrity of the pattern before etching. After development, an inspection is performed to ensure that the photoresist has been applied correctly to within the specified tolerance. At this points, mistakes or unacceptable process variations can be corrected since the photoresist process has not yet produced any changes to the wafer substrate. Photoresist patterns deemed defective can be stripped from the wafer and reworked. A misaligned or otherwise defective photoresist pattern must be removed for reimaging after development and inspection.

Three basic types of photoresist stripping methods include organic stripping, oxidizing-type inorganic stripping, and dry etching. Another photoresist stripping method involves burning the remaining photoresist from the substrate using oxygen plasma in a process known as oxygen plasma ashing. Recently, the oxygen plasma etching method has become the preferred method for removal of photoresist because oxygen plasma can easily burn photoresist to vaporized substances such as carbon dioxide, carbon monoxide and water, and thus remove the photoresist film from the substrate. Furthermore, the process is carried out in a vacuum chamber and is less susceptible to particulate or metallic contamination.

According to one oxygen plasma etching method, the oxygen plasma etching is applied first to partially remove the photoresist film. Next, a wet stripping is applied to completely remove organic photoresists, as well as inorganic plasma etching residues. Finally, removal of the partially removed photoresists and plasma residues is accomplished by exposing the substrate to a wet stripper. The main objective in photoresist stripping is to ensure that all the photoresist is removed as quickly and uniformly as possible without attacking any underlying surface materials, especially metal layers.

FIG. 1 illustrates a typical conventional GDP (gas distribution plate) assembly 10 for a conventional DPS strip chamber 20, shown in FIG. 2. Such a DPS strip chamber 20 includes a chamber interior 21 having a chamber wall 22 and in which is mounted a wafer support 23 for supporting a wafer 24 for the stripping of photoresist from the wafer 24 during a plasma ashing process. A pair of pumping plates 25, each having multiple plasma evacuation apertures 26, is provided in the chamber interior 21 on respective sides of the wafer support 23 for evacuation of the etchant plasma from the chamber interior 21 to a pumping port 28 through respective pumping channels 27.

The GDP assembly 10 typically includes a nozzle plate 12, having a central nozzle opening 13; an upper GDP (gas distribution plate) 14 beneath the nozzle plate 12 and having multiple clustered plasma flow openings 15 in the central region thereof; and a lower GDP (gas distribution plate) 16 beneath the upper GDP 12 and having multiple plasma distribution openings 17 of uniform diameter, typically about 2.5 mm each. The plasma distribution openings 17 are more or less randomly distributed among the central, middle and peripheral or edge portions of the lower GDP 16. Spacers 18 separate the nozzle plate 12 from the upper GDP 14 and the upper GDP 14 from the lower GDP 16.

As shown in FIG. 1, during a plasma ashing process used to strip a layer of photoresist (not shown) from the wafer 24 supported on the wafer support 23, plasma flows respectively through the central nozzle opening 13 of the nozzle plate 12, the plasma flow openings 15 of the upper GDP 14, and the plasma distribution openings 17 of the lower GDP 16. The plasma distribution openings 17 distribute the plasma over the surface of the wafer 24. However, because the clustered plasma flow openings 15 are concentrated in the center region of the upper GDP 14, the plasma distribution openings 17 in the center region of the lower GDP 16 receive the highest concentrations of plasma, whereas the plasma distribution openings 17 in the middle and edge regions of the lower GDP 16 receive plasma which is correspondingly less dense. Consequently, the density of the plasma which contacts the center of the underlying wafer 24 is higher than is the density of the plasma which contacts the middle and edge regions of the wafer 24. This results in disparities in the etch rate among the central, middle and peripheral or edge regions of the wafer 24, with the central region having the highest etch rate, the edge regions having the lowest etch rate, and the middle region having an etch rate intermediate that of the central and edge regions.

The nonuniform distribution of plasma onto the wafer 24 from the lower GDP 16 is exacerbated by the bidirectional flow of unreacted plasma from the chamber interior 21 to the pumping port 28. As shown in FIG. 2, the unreacted plasma flows from the chamber interior 21 through the pumping plates 25 disposed at opposite ends of the chamber 20. Consequently, the areas of the wafer 24 indicated by the reference numerals 2 and 4 receive inadequate concentrations of plasma, whereas the areas of the wafer 24 indicated by the reference numerals 3 and 5 receive excessively high concentrations of plasma. When the density of the plasma contacting the wafer 24 is non-uniform among the various regions of the wafer 24, as heretofore described, the highest-density plasma, at the center (reference numeral 1) of the wafer 24, ignites at a faster rate than does the correspondingly lower-density plasma at the middle and edge regions of the wafer 24. Accordingly, the etch rates on the wafer 24 are higher at the areas indicated by the numerals 3 and 5 than at the areas indicated by the numerals 2 and 4, which indicate “dead spots” representing little or no plasma flow against the wafer surface. The etch rate is the highest at the center of the wafer 24, indicated by reference numeral 1.

FIG. 3 is a schematic view of the lower GDP 16, separated into 9 regions designated “A1”, “B1”, “B2”, “B3”, “B4”, “C1”, “C2”, “C3”, and “C4”, respectively. The etch rate imparted on the wafer by the plasma flowing through the plasma distribution openings 17 in each of those respective regions is proportional to the total area of the apertures in each region divided by the average distance between the apertures in the region and the wafer surface, multiplied by the reciprocal of the square root of the average distance between the apertures in the region and the pump port. This is expressed by the equation: R_{E}∝A1/D1×1/sq.r.d1, where A1 is the combined areas of the apertures in each region; D1 is the average distance between the apertures in the region and the wafer surface; and sq.r.d1 is the square root of the average distance between the apertures in the region and the pump port of the chamber. Accordingly, under circumstances in which the values D1 and d1 are constant, the etch rates of the plasma flowing through the various regions of the lower GDP can be altered only by changing the value A1, which is the combined areas of the apertures in each region.

The relative etch rates of the plasma flowing through the openings 17 in the respective regions A1, B1, B2, B3, B4, C1, C2, C3, and C4 of the conventional lower GDP 16 are 22990:21408:21925:21536:21893:18159:20561:18231:20732. In the lower GDP 16, the combined areas of all plasma distribution openings 17 for each of the 9 regions is the same as each of the other regions. Thus, the ratio of combined areas for the openings 17 in the respective regions is 1:1:1:1:1:1:1:1:1. The average shortest distance, in millimeters, between the openings 17 in each of the 9 regions and the surface of the wafer 24 is 60.7:63.2:63.2:63.2:63.2:77.3:77.3:77.3:77.3. Thus, the distance between the wafer 24 and the openings 17 in the central region (A1) of the lower GDP 16 is greater than the distance between the wafer 24 and the openings 17 in the middle region (B1-B4) of the lower GDP 16. Likewise, the distance between the wafer 24 and the openings 17 in the middle region (B1-B4) of the lower GDP 16 is greater than the distance between the wafer 24 and the openings 17 in the edge regions (C1-C4) of the lower GDP 16. Accordingly, the non-uniform etch rates of the plasma on the surface of the wafer 24 is due to the disparity in distances between the wafer 24 and the openings 17 in the various regions of the lower GDP 16, in combination with the equality in combined areas of the openings 17 among the nine regions of the lower GDP 16.

Accordingly, an object of the present invention is to provide for the uniform distribution of plasma among all areas of a substrate in a substrate processing chamber.

Another object of the present invention is to provide a new and improved gas distribution plate which facilitates uniform etching among all areas of a substrate in a processing chamber.

Still another object of the present invention is to provide a gas distribution plate which provides for enhanced plasma flow to the edge regions of a substrate to compensate for correspondingly higher plasma flow to the central region of the substrate during etching of the substrate.

Yet another object of the present invention is to provide a gas distribution plate which overcomes design deficiencies in the prior art to enhance uniformity in plasma flow and etching to all areas on the surface of a substrate.

A still further object of the present invention is to provide a gas distribution plate which includes a relatively higher area for plasma distribution through the peripheral or edge regions of the plate as compared to the central region of the plate in order to compensate for the normally higher flow rate of plasma through the center of the plate to the central region of a substrate.

Yet another object of the present invention is to provide a method of enhancing plasma flow to the edge regions of a substrate to facilitate more uniform etch rates among the various regions of the substrate.

### SUMMARY OF THE INVENTION

In accordance with these and other objects and advantages, the present invention comprises a new and improved gas distribution plate for a processing chamber for substrates. The gas distribution plate is provided with multiple gas distribution openings which are larger in size in the peripheral or edge regions of the plate than are the openings in the central region of the plate. The larger openings in the peripheral or edge regions of the plate provide a greater area for gas distribution through the plate than the smaller openings in the central region of the plate in order to compensate for the normally higher rate of plasma flow through the center region of the plate.

### BRIEF DESCRIPTION OF THE DRAWINGS

The invention will now be described, by way of example, with reference to the accompanying drawings, in which:

FIG. 1 is an exploded, perspective view of a typical conventional GDP (gas distribution plate) assembly for a process chamber for substrates;

FIG. 2 is a schematic view illustrating typical flow of plasma through a gas distribution plate and conventional processing chamber;

FIG. 3 is a schematic view illustrating division of a lower gas distribution plate of a GDP assembly into nine regions of gas distribution flow through the plate;

FIG. 4 is an exploded, perspective view of a GDP assembly of the present invention;

FIG. 5 is a schematic view illustrating division of a lower gas distribution plate of a GDP assembly of the present invention into nine regions of gas distribution flow through the plate; and

FIG. 6 is a schematic view illustrating substantially uniform flow of plasma through the lower gas distribution plate of the present invention and onto a wafer in a processing chamber.

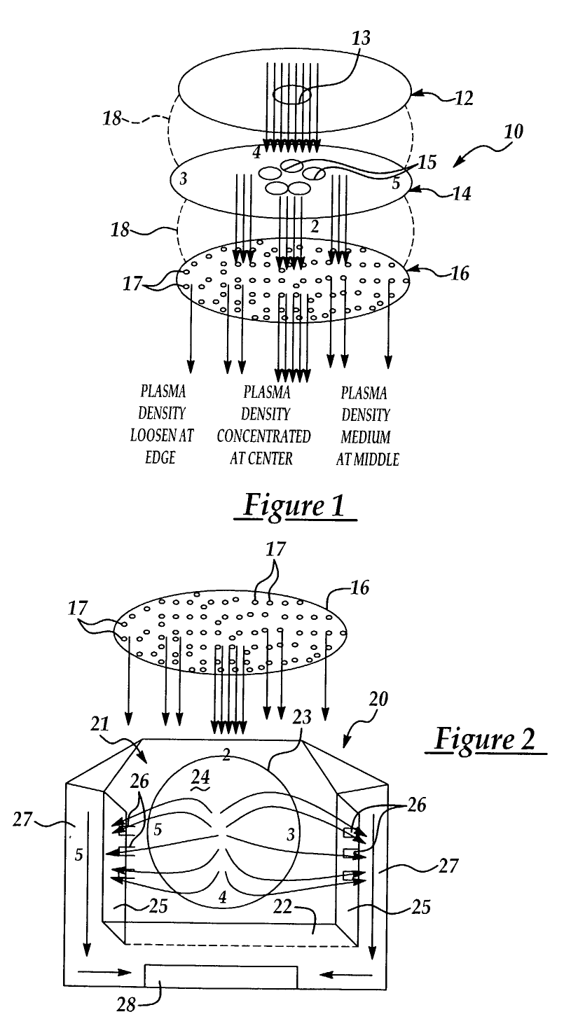

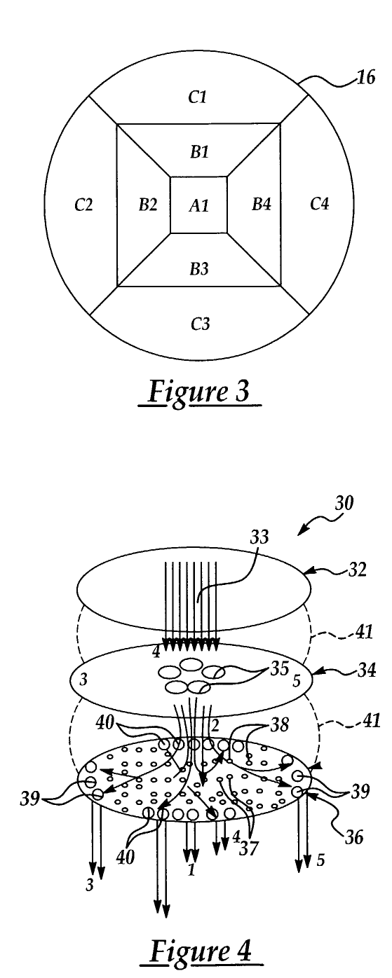

### DESCRIPTION OF THE PREFERRED EMBODIMENTS

The present invention is directed to a GDP assembly for a processing chamber for processing semiconductor substrates, particularly a DPS strip chamber supplied by the Applied Materials Corp. of Santa Clara, Calif. However, the GDP assembly of the present invention may be applicable to other types of substrate processing chambers known by those skilled in the art. The GDP assembly of the present invention facilitates substantial uniformity in plasma flow onto central, middle and peripheral regions of a semiconductor wafer for the uniform plasma etching of those regions on the wafer.

Referring initially to FIG. 4, the GDP assembly of the present invention is generally indicated by reference numeral 30 and typically includes a nozzle plate 32, having a central nozzle opening 33 for receiving a plasma (not shown), in conventional fashion. An upper GDP (gas distribution plate) 34 beneath the nozzle plate 32 includes multiple, typically five, plasma flow openings 35 clustered in the central region thereof. A lower GDP (gas distribution plate) 36 is disposed beneath the upper GDP 34. Spacers 41 separate the nozzle plate 32 from the upper GDP 34 and the upper GDP 34 from the lower GDP 36.

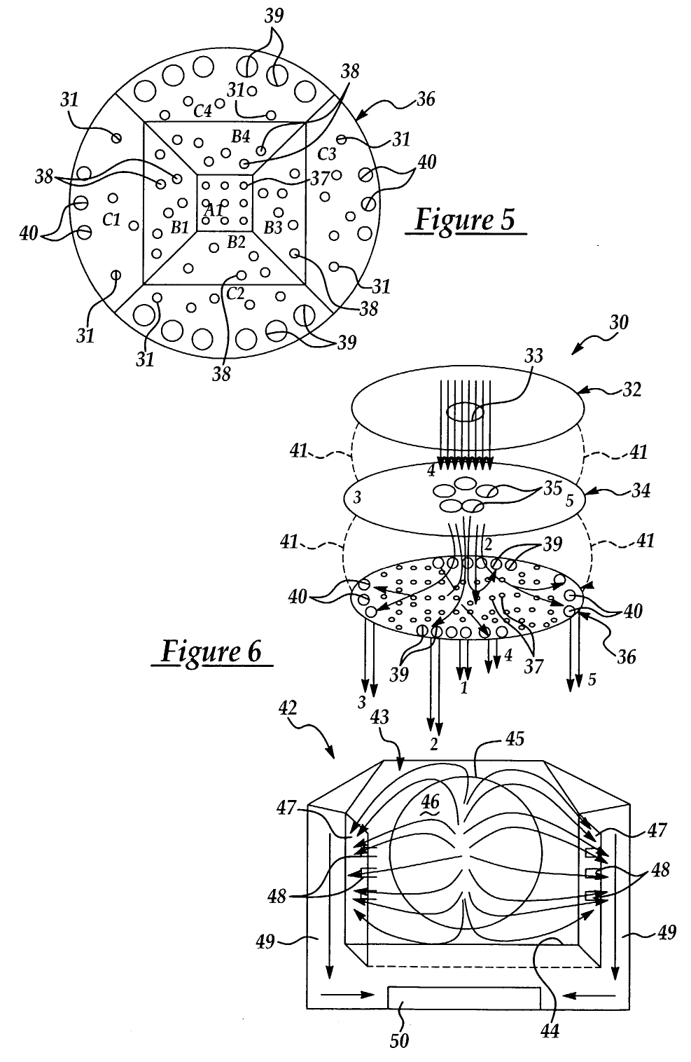

As shown in FIG. 5, for purposes,of discussion the lower GDP 36 may be divided into nine regions, designated “A1”, “B1”, “B2”, “B3”, “B4”, “C1”, “C2”, “C3”, and “C4”, respectively, the boundaries between which regions are imaginary and indicated by the dark lines. The nine regions may have areas (mm²) as follows: A1—2500 mm²; B1, B2, B3, B4—3281 mm², respectively; and C1, C2, C3, C4—4748.5 mm², respectively. The central area on the lower GDP 36 is the central region A1, whereas a concentric middle area on the lower GDP 36 is defined by the combined middle regions B1-B4. A concentric peripheral area on the lower GDP 36 is defined by the combined peripheral regions C1-C4. The central area, or region “A1”, typically includes nine central plasma distribution openings 37, each of which extends through the lower GDP 36 and may have a diameter in the range of about 1.5 mm to about 2.5 mm, and preferably, about 2.1 mm. Each of the middle regions B1-B4, respectively, of the middle area has multiple middle plasma distribution openings 38, each of which extends through the lower GDP 36 and may have a diameter in the range of about 2.0 to about 3.0 mm, and preferably, about 2.5 mm. Each of the middle regions B1-B4 may have typically from about 3-10 of the openings 38 for a combined number of about 12-40 gas distribution openings 38 in the middle area defined by the regions B1-B4. Each of the peripheral regions C1 and C3, respectively, which correspond to the respective pumping plates 47 of a DPS strip chamber 42, as shown in FIG. 6, is provided with multiple, typically three, peripheral plasma distribution openings 40 each of which may have a diameter in the range of about 3.0 mm to about 4.0 mm, and preferably, about 3.6 mm, in diameter. Each of the peripheral regions C2 and C4, respectively, which correspond to the portions of the chamber 42 between the pumping plates 47, is provided with multiple, typically six, peripheral plasma distribution openings 39 each of which may have a diameter in the range of about 5.5 mm to about 6.5 mm, and preferably, about 6.0 mm, in diameter. Additional smaller openings 31, each of which may have a diameter of about 2.5 mm, may extend through the lower GDP 36 in each of the peripheral regions C1-C4. The smaller openings 31 may number about 2-6 in each of the peripheral regions C1-C4, for a total number of about 8-24 of the smaller openings 31 in the peripheral area of the lower GDP 36.

Referring next to FIG. 6, in application the GDP assembly 30 is installed in a processing chamber such as a conventional DPS strip chamber 42, according to the knowledge of those skilled in the art. The DPS strip chamber 42 includes a chamber interior 43 having a chamber wall 44 and in which is mounted a wafer support 45 for supporting a wafer 46 for the stripping of photoresist from the wafer 46 during a plasma ashing process, using parameters known by those skilled in the art. When the GDP assembly 30 is installed in the chamber interior 21, the average shortest distance, in millimeters, between the surface of the wafer 46 and the gas distribution openings in each of the 9 regions A1, B1-B4, and C1-C4 is typically 60.7:63.2:63.2:63.2:63.2:77.3:77.3:77.3:77.3 mm, respectively. A pair of pumping plates 47, each having multiple plasma evacuation apertures 48, is provided in the chamber interior 43 on respective sides of the wafer support 45 for evacuation of the etching plasma from the chamber interior 43 to a pumping port 50 through pumping channels 49. During a plasma ashing process used to strip a layer of photoresist (not shown) from the wafer 46 supported on the wafer support 45, plasma flows respectively through the central nozzle opening 33 of the nozzle plate 32 and the plasma flow openings 35 of the upper GDP 34. Next, the plasma flows simultaneously through the central plasma distribution openings 37 in the central region A1, the middle plasma distribution openings 38 in the middle regions B1-B4, respectively, the peripheral openings 39 in the peripheral regions C2 and C4, respectively, the peripheral openings 40 in the peripheral regions C1 and C3, respectively, and the smaller openings 31 in the peripheral regions C1-C4, respectively, of the lower GDP. Accordingly, due to the increasingly large sizes of the openings 37 in the central region A1, the openings 38 in the middle regions B1-B4, the openings 40 in the peripheral regions C1 and C3, respectively, and the openings 39 in the peripheral regions C2 and C4, respectively, plasma flow through the lower GDP 36 is substantially uniform. Consequently, equal quantities of plasma contact the central, middle and peripheral regions on the surface of the wafer 46.

The peripheral plasma distribution openings 39 in each of the peripheral regions C2 and C4 typically are greater in number and diameter than are the peripheral plasma openings 40 in each of the peripheral regions C1 and C4, because the smaller openings 40 are disposed adjacent to the respective pumping plates 47 of the chamber 42 and thus, are positionally subjected to a stronger plasma flow effect than are the larger openings 39. The net result is generation of a plasma flow profile which is substantially uniform throughout all regions of the lower GDP 36 for uniform contact and etching of all regions on the wafer 46.

While the preferred embodiments of the invention have been described above, it will be recognized and understood that various modifications can be made in the invention and the appended claims are intended to cover all such modifications which may fall within the spirit and scope of the invention.

What is claimed is:

1. A gas distribution plate assembly for a process chamber, comprising:
a gas distribution plate;
a plurality of central openings extending through a central area of said plate;
a plurality of peripheral openings extending through a peripheral area of said plate, each of said peripheral openings having a diameter larger than a diameter of said central openings, respectively; and
a plurality of middle openings extending through a middle area of said plate between said central area and said peripheral area, each of said middle openings having a diameter between said diameter of said central openings and said diameter of said peripheral openings.

2. The assembly of claim 1 wherein said diameter of said central openings is about 1.5 mm to about 2.5 mm.

3. The assembly of claim 1 wherein said diameter of said peripheral openings is about 3.0 mm to about 6.5 mm.

4. The assembly of claim 3 wherein said diameter of said central openings is about 1.5 mm to about 2.5 mm.

5. The assembly of claim 1 wherein said diameter of said middle openings is about 2.0 mm to about 3.0 mm.

6. The assembly of claim 5 wherein said diameter of said central openings is about 1.5 mm to about 2.5 mm.

7. The assembly of claim 5 wherein said diameter of said peripheral openings is about 3.0 mm to about 6.5 mm.

8. The assembly of claim 7 wherein said diameter of said central openings is about 1.5 mm to about 2.5 mm.

9. The assembly of claim 1 wherein said peripheral area comprises first and second peripheral regions located at diametrically-opposed positions to each other on said plate and third and fourth peripheral regions located at diametrically-opposed positions to each other on said plate; wherein said plurality of peripheral openings comprises first and second groups of peripheral openings extending through said plate in said first and second peripheral regions, respectively, and third and fourth groups of peripheral openings extending through said plate in said third and fourth peripheral regions, respectively; wherein said first and second groups of peripheral openings each comprises openings having a first diameter; and wherein said third and fourth groups of peripheral openings each comprises openings having a second diameter greater than said first diameter.

10. The assembly of claim 9 wherein said diameter of said central openings is about 1.5 mm to about 2.5 mm.

11. The assembly of claim 9 wherein said diameter of said middle openings is about 2.0 mm to about 3.0 mm.

12. The assembly of claim 11 wherein said diameter of said central openings is about 1.5 mm to about 2.5 mm.

13. The assembly of claim 9 wherein said first diameter is in the range of about 3.0 mm to about 4.0 mm and said second diameter is in the range of about 5.5 mm to about 6.5 mm.

14. The assembly of claim 13 wherein said diameter of said central openings is about 1.5 mm to about 2.5 mm.

15. The assembly of claim 13 wherein said diameter of said middle openings is about 2.0 mm to about 3.0 mm.

16. The assembly of claim 15 wherein said diameter of said central openings is about 1.5 mm to about 2.5 mm.

17. A gas distribution plate assembly for a process chamber, comprising:
a gas distribution plate;
a plurality of central openings extending through a central area of said plate, said central openings each having a diameter of about 2.1 mm;
a plurality of peripheral openings extending through a peripheral area of said plate, each of said peripheral openings having a diameter of about 3.0 to about 6.0 mm; and
a plurality of middle openings extending through a middle area of said plate between said central area and said peripheral area, each of said middle openings having a diameter of about 2.5 mm.

18. The gas distribution plate of claim 17 wherein said peripheral area comprises first and second peripheral regions located at diametrically-opposed positions to each other on said plate and third and fourth peripheral regions located at diametrically-opposed positions to each other on said plate; wherein said plurality of peripheral openings comprises first and second groups of peripheral openings extending through said plate in said first and second peripheral regions, respectively, and third and fourth groups of peripheral openings extending through said plate in said third and fourth peripheral regions, respectively; wherein said first and second groups of peripheral openings each comprises openings having a first diameter; and wherein said third and fourth groups of peripheral openings each comprises openings having a second diameter greater than said first diameter.

19. The gas distribution plate of claim 18 wherein said first diameter is about 3.6 mm and said second diameter is about 6.0 mm.

20. A gas distribution plate assembly for a process chamber, comprising:
a nozzle plate having a central nozzle opening;
an upper gas distribution plate disposed beneath said nozzle plate and having a plurality of plasma flow openings;
a lower gas distribution plate disposed beneath said upper gas distribution plate;
a plurality of central openings extending through a central area of said lower gas distribution plate;
a plurality of peripheral openings extending through a peripheral area of said lower gas distribution plate, each of said peripheral openings having a diameter larger than a diameter of said central openings, respectively; and
a plurality of middle openings extending through a middle area of said lower gas distribution plate between said central area and said peripheral area, each of said middle openings having a diameter between said diameter of said central openings and said diameter of said peripheral openings.
